(19) United States
(12) Patent Application Publication
(10) Pub. No.: US 2015/0028938 A1
(43) Pub. Date: Jan. 29, 2015

(54) CHARGE PUMPING DEVICE

(71) Applicants: SK HYNIX INC., Icheon (KR); Industry-Academic Cooperation Foundation, Yonsei University, Seoul (KR)

(72) Inventors: Choong-Keun LEE, Miryang (KR); Hong-Il YOON, Seoul (KR)

(21) Appl. No.: 14/512,975

(22) Filed: Oct. 13, 2014

Related U.S. Application Data
(63) Continuation of application No. 13/762,333, filed on Feb. 7, 2013.

(30) Foreign Application Priority Data
Feb. 14, 2012 (KR) 10-2012-0014771

(51) Int. Cl. H02M 3/07; H03K 3/012

(52) U.S. Cl. CPC H02M 3/07; H03K 3/012
USPC 327/536

(57) ABSTRACT

A charge pumping device includes unit cells. Each unit cell includes first and second cells, each including a charge transfer circuit, a switch controlling a charge transfer operation thereof, and a charge storage circuit having a first end connected to an output terminal of the charge transfer circuit. The switch of the first and second cell is controlled by a first and second clock and the output terminal of the second and first cell, respectively. The first and second clocks are inputted to a second end of the charge storage circuit of the second and first cells, respectively. A first interface circuit connects first and second cells of a first unit cell to second and first cells of a second unit cell, respectively. Output terminals of a final unit cell connect to a load capacitor. Input terminals of an initial unit cell connect to a supply voltage.

This application is a continuation of U.S. application Ser. No. 13/762,333, filed on Feb. 7, 2013, which claims the benefit under 35 U.S.C. §119(a) of Korean Application No. 10-2012-0014771, filed on Feb. 14, 2012. The specification and claims thereof are incorporated herein by reference.

### BACKGROUND

1. Technical Field

The present invention relates to a charge pumping device and a unit cell thereof. Particularly, the present invention relates to a charge pumping device having a high pumping efficiency at a low power supply voltage and a unit cell thereof. More particularly, the present invention relates to a charge pumping device having a high pumping efficiency at a power supply voltage of approximately 1 V or less and a unit cell thereof.

2. Related Art

In an electronic circuit such as a semiconductor memory apparatus, in order to use an internal voltage higher than an external power supply voltage, it is general to use a charge pumping device that generates an internal power supply voltage from the external power supply voltage.

Recently, in various electronic apparatuses such as portable electronic appliances, a power supply voltage is gradually reduced in order to reduce power consumption. For example, in a current LPDDR2 standard for a low power semiconductor memory apparatus, the use of an external power supply voltage of approximately 1.2 V is stipulated, and it is estimated that a semiconductor memory apparatus using an external power supply voltage of approximately 1 V or less will be commercialized in the near future. In this regard, there has been an increased demand for a charge pumping device that efficiently operates at a low power supply voltage, particularly, at an external power supply voltage of approximately 1 V or less.

FIG. 1 is a circuit diagram illustrating a Dickson charge pumping device that is a representative example of a charge pumping device. The Dickson charge pumping device has a configuration in which unit cells including a diode or a diode-connected transistor 10 and a pumping capacitor 20 are serially connected to one another. In such a configuration, pumping clocks clk1 and clk2 are inputted to one end of the pumping capacitor of each unit cell, wherein the phases of pumping clocks input to the adjacent unit cells are opposite to each other. Since the Dickson pumping circuit is well-known in the art, a description for a detailed operation thereof will be omitted.

Conventional charge pumping devices such as the Dickson pumping circuits require a large number of unit cells in order to generate a high internal voltage. Therefore, the Dickson pumping circuits also require a larger number of unit cells to generate a high internal voltage as the external power supply voltage is reduced.

In such conventional circuits, as the number of cells is increased, a threshold voltage is increased due to a body effect. Furthermore, in such conventional circuits, since voltage drop occurs in proportion to a threshold voltage, loss occurs in an output voltage. As a consequence, as the number of unit cells is increased, the degree of an increase in a pumping voltage is also reduced, resulting in the deterioration of pumping efficiency.

### SUMMARY

A unit cell for a charge pumping device having a high pumping efficiency at a low power supply voltage, a charge pumping device, and/or a semiconductor apparatus including the same are described herein.

Particularly, a unit cell for a charge pumping device having a high pumping efficiency at a low power supply voltage of approximately 1 V or less, a charge pumping device, and/or a semiconductor apparatus including the same are described herein.

In one embodiment of the present invention, a unit cell having a high pumping efficiency at a low power supply voltage is disclosed. The unit cell includes a first cell including a first charge transfer unit, a first switch for controlling a charge transfer operation of the first charge transfer unit, and a first charge storage unit having one end connected to an output terminal of the first charge transfer unit and storing charge. The unit cell includes a second cell including a second charge transfer unit, a second switch for controlling a charge transfer operation of the second charge transfer unit, and a second charge storage unit having one end connected to an output terminal of the second charge transfer unit and storing charge. In the unit cell, the first switch is controlled by a first clock and an output terminal of the second charge storage unit, the second switch is controlled by a second clock and an output terminal of the first charge storage unit, the second clock is inputted to the other end of the first charge storage unit, and the first clock is inputted to the other end of the second charge storage unit.

In another embodiment of the present invention, a charge pumping device includes N unit cells (where N is a natural number or integer). In the charge pumping device, input terminals of a first charge transfer unit and a second charge transfer unit of a first stage are commonly connected to a power supply voltage (e.g., a power supply voltage that is external to the charge pumping device). The charge pumping device further includes a first interface unit that exists when N is a natural number (integer) equal to or more than 2, connects an output terminal of a first charge transfer unit of a k^{th} (k is a natural number, or integer, from 1 to N−1) stage to an input terminal of a first charge transfer unit of a k+1^{th} stage, and connects an output terminal of a second charge transfer unit of the k^{th} stage to an input terminal of a second charge transfer unit of the k+1^{th} stage. The charge pumping device further includes a second interface unit that connects an output terminal of a first charge transfer unit of an N^{th} stage and an output terminal of a second charge transfer unit of the N^{th} stage to one end of a load capacitor.

In another embodiment of the present invention, a charge pumping device includes N unit cells (where N is a natural number or integer). In the charge pumping device, input terminals of a first charge transfer unit and a second charge transfer unit of a first stage are commonly connected to a power supply voltage (e.g., a power supply voltage that is external to the charge pumping device). The charge pumping device further includes a first interface unit that exists when N is a natural number equal to or more than 2, connects an output terminal of a first charge transfer unit of a k^{th} (k is a natural number, or integer, from 1 to N−1) stage to an input terminal of a first charge transfer unit of a k+1^{th} stage, and connects an output terminal of a second charge transfer unit of an adjacent k^{th} stage to an input terminal of a second charge transfer unit of the k+1^{th} stage. The charge pumping device includes a second interface unit that connects an output terminal of a first charge transfer unit of an N^{th} stage to one end of a load capacitor.

In another embodiment of the present invention, a semiconductor apparatus including the unit cell and the charge pumping device is disclosed.

A unit cell for a charge pumping device according to an embodiment of the invention and a charge pumping device using the same provide superior pumping performance at a low power supply voltage, particularly, at a low power supply voltage of approximately 1 V or less.

The charge pumping device according to an embodiment of the invention has high pumping efficiency because the voltage drop due to a threshold voltage does not occur even when the number of unit cells is increased in the charge pumping device.

In addition to the above effects, a symmetric charge pumping device according to an embodiment of the invention alternately performs pumping in two parallel cells, thereby enabling high speed pumping. An asymmetric charge pumping device according to an embodiment of the invention is able to reduce an area occupied by a circuit.

### BRIEF DESCRIPTION OF THE DRAWINGS

Features, aspects, and embodiments are described in conjunction with the attached drawings, in which:

FIG. 1 is a circuit diagram illustrating a charge pumping device in the conventional art;

FIG. 2 is a block diagram of a unit cell of a charge pumping device according to an embodiment of the present invention;

FIG. 3 is a circuit diagram of a unit cell of a charge pumping device according to an embodiment of the present invention;

FIG. 4 is a circuit diagram of a charge pumping device according to an embodiment of the present invention;

FIG. 5 is a circuit diagram of a charge pumping device according to another embodiment of the present invention;

FIG. 6 is a graph illustrating a difference of pumping performance according to an increase in the number of unit cells; and

FIG. 7 is a graph illustrating a difference of pumping performance according to the magnitude of a power supply voltage.

### DETAILED DESCRIPTION

Hereinafter, a charge pumping device and a unit cell thereof according to the present invention will be described in detail with reference to the accompanying drawings through an exemplary embodiment.

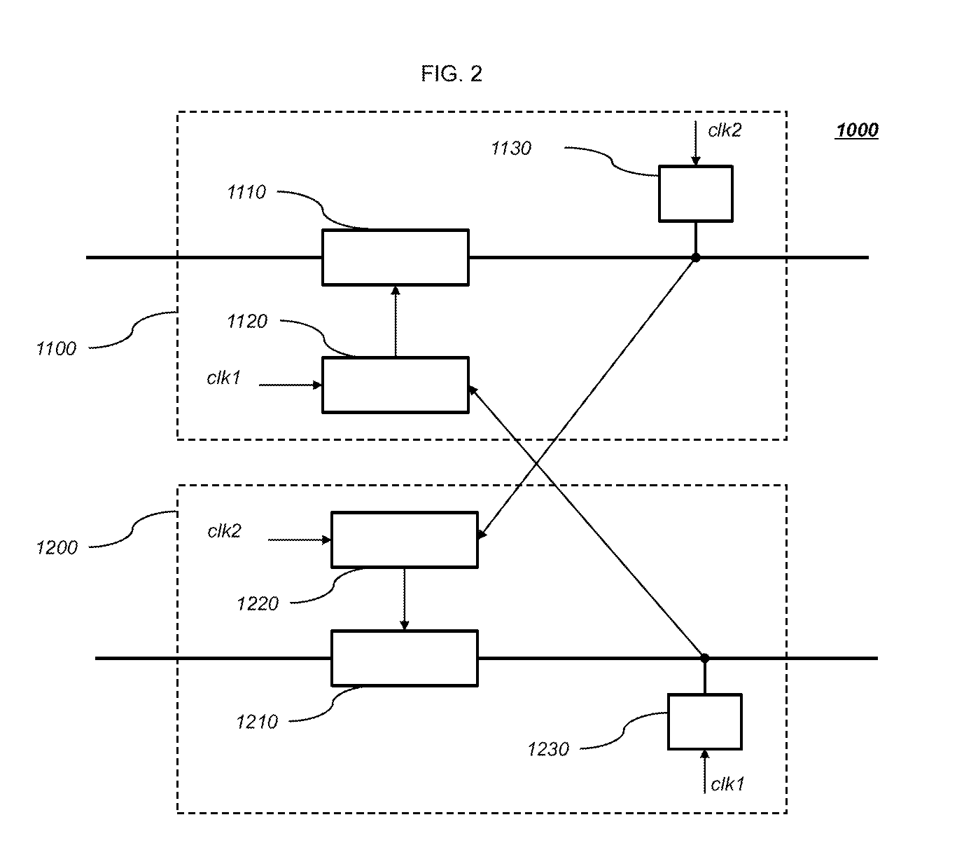

FIG. 2 is a block diagram of a unit cell 1000 of a charge pumping device according to an embodiment of the present invention.

As illustrated in FIG. 2, the unit cell 1000 of the charge pumping device includes a first cell 1100 and a second cell 1200. The first cell 1100 includes a first charge transfer unit 1110, a first switch 1120 that controls a charge transfer operation of the first charge transfer unit 1110, and a first charge storage unit 1130 having one end connected to an output terminal of the first charge transfer unit 1110. Similarly to the first cell 1100, the second cell 1200 includes a second charge transfer unit 1210, a second switch 1220, and a second charge storage unit 1230. The output terminal of the first charge storage unit 1130 is coupled to the output terminal of the first cell 1100. The output terminal of the second charge storage unit 1230 is coupled to the output terminal of the second cell 1200.

The first switch 1120 controls an operation (that is, a charge transfer operation) in which charge passes through the first charge transfer unit 1110 and is stored in the first charge storage unit 1130, or controls an operation (that is, a charge backflow prevention operation) for substantially preventing charge stored in the first charge storage unit 1130 from flowing back through the first charge transfer unit 1110. To this end, the first switch 1120 is controlled by a first clock clk1 and an output terminal of the second charge transfer unit 1210. To this end, the first switch 1120 may include a 1-1^{th} switch (not illustrated) controlled by the first clock clk1 and a 1-2^{th} switch (not illustrated) controlled by the output terminal of the second charge transfer unit 1210.

The second switch 1220 also performs an operation similar to that of the first switch 1120. To this end, the second switch 1220 is controlled by a second clock clk2 and the output terminal of the first charge transfer unit 1110. Similarly, the second switch 1220 may include a 2-1^{th} switch (not illustrated) controlled by the second clock clk2 and a 2-2^{th} switch (not illustrated) controlled by the output terminal of the first charge transfer unit 1110.

Furthermore, the second clock clk2 and the first clock clk1 are inputted to the other end of the first charge storage unit 1130 and the other end of the second charge storage unit 1230, respectively.

The first clock clk1 and the second clock clk2 are square waves having phases opposite to each other, and have amplitudes substantially equal to the magnitude of a power supply voltage.

Although not illustrated in the drawing, the first cell 1100 and the second cell 1200 may include bias control units for setting bias voltages of the first charge transfer unit 1110 and the second charge transfer unit 1210, respectively. The function of the bias control unit will be described below.

An operation of the unit cell 1000 will be described as follows. When the charge transfer operation is performed in the first cell 1100, the charge backflow prevention operation is performed in the second cell 1200. Additionally, when the charge backflow prevention operation is performed in the first cell 1100, the charge transfer operation is performed in the second cell 1200. Accordingly, for one cycle of the first clock clk1 and the second clock clk2, the first cell 1100 simultaneously performs the charge transfer operation and the charge backflow prevention operation, and the second cell 1200 simultaneously performs the charge backflow prevention operation and the charge transfer operation.

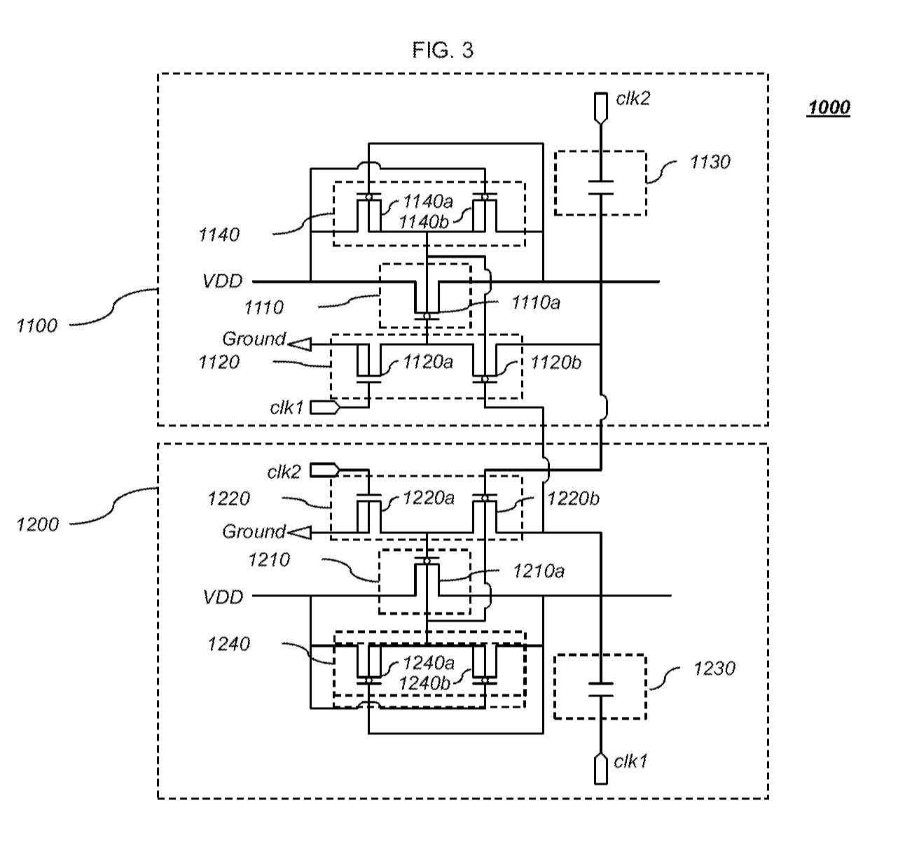

FIG. 3 is a circuit diagram of the unit cell 1000 for the charge pumping device according to an embodiment of the present invention, which corresponds to the block diagram illustrated in FIG. 2.

As illustrated in FIG. 3, each of the first charge transfer unit 1110 and the second charge transfer unit 1210 includes a PMOS transistor, and each of the first charge storage unit 1130 and the second charge storage unit 1230 includes a capacitor.

The first switch 1120 includes a NMOS transistor and a PMOS transistor, wherein drains of the NMOS transistor and the PMOS transistor are connected to each other and a gate of the PMOS transistor of the first charge transfer unit 1110 is controlled by voltages of the connected drains of the NMOS transistor and PMOS transistor in the first switch 1120.

Based on the assumption that input terminals of the first charge transfer unit 1110 and the second charge transfer unit 1210 are connected to a power supply voltage VDD (that is, the unit cell 1000 is a first stage of the charge pumping device), an operation of the first switch 1120 will be described as follows.

The NMOS transistor 1120a of the first switch 1120 serves as the aforementioned the 1-1^{th} switch and controls the charge transfer operation. That is, when the first clock clk1 is in a ‘High’ state, the NMOS transistor 1120a is turned on to turn on the first charge transfer unit 1110, so that charge moves to the first charge storage unit 1130 through the first charge transfer unit 1110. In other words, when the first clock clk1 is ‘High’, the first clock clk1 will turn on the NMOS transistor 1120a and the NMOS transistor 1120a will pull the ground voltage ‘Ground’ value at the source of the NMOS transistor 1120a to the drain of the NMOS transistor 1120a. The ground voltage ‘Ground’ value at the drain of the NMOS transistor 1120a is also input into the gate of the PMOS transistor 1110a (which forms the first charge transfer unit 1110) and turns on the PMOS transistor 1110a. Since the PMOS transistor 1110a is turned on, the PMOS transistor 1110a will pull the power supply voltage VDD value at the drain of the PMOS transistor 1110a to the source of the PMOS transistor 1110a. Since the source of the PMOS transistor 1110a is pulled to the power supply voltage VDD value, the power supply voltage VDD value is driven into a terminal of the first charge storage unit 1130 connected to the source of the PMOS transistor 1110a in response to the PMOS transistor 1110a as having turned on. At this time, a voltage difference corresponding to the power supply voltage VDD is formed at both ends of the first charge storage unit 1130. The power supply voltage VDD is, for example, a power supply voltage that is external to a charge pumping device according to an embodiment of the invention.

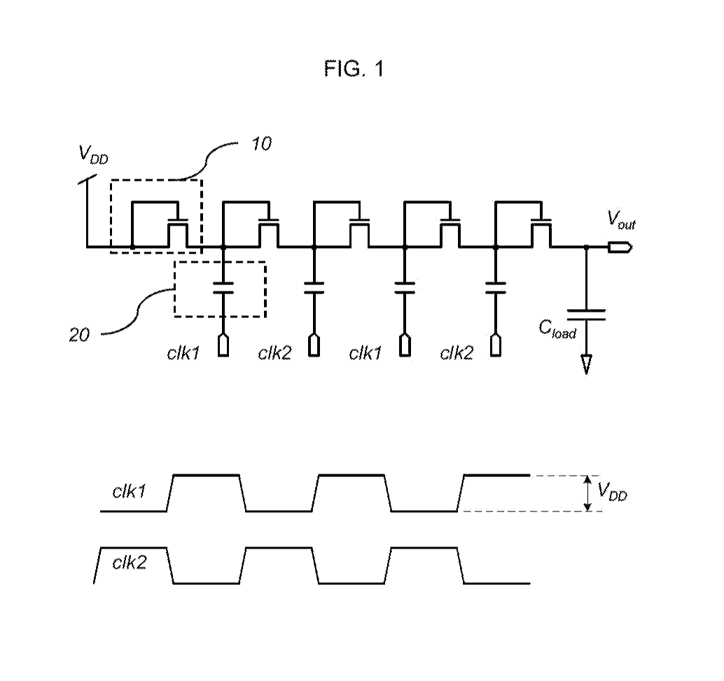

The PMOS transistor 1120b of the first switch 1120 serves as the aforementioned the 1-2^{th} switch and controls the charge backflow prevention operation. That is, when the first clock clk1 is changed to a ‘LOW’ state, since the second clock clk2 is in a ‘HIGH’ state (see, e.g., the clocks clk1 and clk2 in FIG. 1), a voltage of the output terminal of the first charge transfer unit 1110 is 2VDD. The charge of the first charge storage unit 1130 does not change according to the law of charge conservation. The amount of charge stored in a capacitor is decided by capacitance thereof and voltage between the electrodes thereof. Since the capacitance of the first charge storage unit 1130 is fixed, the amount of charge of the first charge storage unit 1130 depends on the voltage applied thereto. When clk1 is in “HIGH”, whose voltage level is VDD, for charge transfer operation of the PMOS transistor 1110a clk2 is in “LOW”, whose voltage level is 0. That is the voltage of one node of the first charge storage unit 1130 becomes 0 and the other node thereof, which is the output terminal of the first charge transfer unit 1100, becomes VDD. When clk1 becomes “LOW” and clk2 becomes “HIGH”, the voltage of the output terminal of the first charge transfer unit 1100 becomes 2VDD for charge conservation. The voltage may be less than 2VDD for leakage. Simultaneously, since the NMOS transistor 1220a of the second switch 1220 is turned on, a voltage of the output terminal of the second charge transfer unit 1210 is VDD due to charge transfer to the second charge storage unit 1230. When the NMOS transistor 1220a turns on due to the ‘HIGH’ second clock clk2 at the gate of the NMOS transistor 1220a, the NMOS transistor 1220a will pull the ground voltage at the source to the drain of the NMOS transistor 1220a. The ground voltage that is pulled to the drain of the NMOS transistor 1220a will turn on the PMOS transistor 1210a. When the PMOS transistor 1210a is turned on, the PMOS transistor 1220b is also off because the VDD value at the output terminal of the first charge storage unit 1130 is also being driven into the gate of the PMOS transistor 1220b. Since the PMOS transistor 1210a is turned on, the PMOS transistor 1210a will pull the VDD value at the drain to the source of the PMOS transistor 1210a. The VDD value at the source of the PMOS transistor 1210a is driven into the second charge transfer unit 1230 so that a voltage difference corresponding to the power supply voltage VDD is formed at both ends of the second charge storage unit 1230. Thus, the PMOS transistor 1120b of the first switch 1120 is turned on, so that 2VDD is applied to the gate of the first charge transfer unit 1110. Thus, the PMOS transistor 1110a of the first charge transfer unit 1110 is turned off, so that the charge of the first charge storage unit 1130 is substantially prevented from flowing back to the input terminal of the first charge transfer unit 1110.

When charge is transferred through the first charge transfer unit 1110, it is preferable that voltage drop does not occur at both ends of the first charge transfer unit 1110. In the embodiment, in the charge transfer operation, since the gate voltage of the PMOS transistor 1110a of the first charge transfer unit 1110 drops to a ground voltage, the PMOS transistor 1110a operates in a saturation region, so that voltage drop does not occur at both ends of the PMOS transistor 1110a.

Since an operation of the second switch 1220 is substantially equal to that of the first switch 1120, a detailed description thereof will be omitted.

In FIG. 3, the first cell 1100 further includes a first bias control unit 1140 that controls a substrate bias voltage of the PMOS transistor 1110a of the first charge transfer unit 1110 and the PMOS transistor 1120b of the first switch 1120. Similarly, the second cell 1200 further includes a second bias control unit 1240 that controls a substrate bias voltage of the PMOS transistor 1210a of the second charge transfer unit 1210 and the PMOS transistor 1220b. As also shown in FIG. 3, the first bias control unit 1140 and the second bias control unit 1240 are both biased by the supply voltage source VDD.

The first bias control unit 1140 of FIG. 3 includes two PMOS transistors 1140a and 1140b and allows a higher voltage of source and drain voltages of the PMOS transistor 1110a of the first charge transfer unit 1110 to be applied as the substrate bias voltage of the PMOS transistor 1110a of the first charge transfer unit 1110 and the PMOS transistor 1120b of the first switch 1120. As also shown in FIG. 3, the PMOS transistor 1140a has a source connected to the supply voltage source VDD and has a gate connected to the drain of the PMOS transistor 1140b, to output terminal of the first charge storage unit 1130, to the source of the PMOS transistor 1110a, to the source of the PMOS transistor 1120b, and to the gate of the PMOS transistor 1220b. The PMOS transistor 1140b has a source connected to the drain of the PMOS transistor 1140a and has a gate connected to the supply voltage source VDD. The drain of the PMOS transistor 1140b is connected to the gate of the PMOS transistor 1140a, to the output terminal of the first charge storage unit 1130, to the source of the PMOS transistor 1110a, to the source of the PMOS transistor 1120b, and to the gate of the PMOS transistor 1220b. The drain of the PMOS transistor 1140a and the source of the PMOS transistor 1140b are coupled together and are also coupled to the PMOS transistor 1110a and to the PMOS transistor 1120b, so that the PMOS transistors 1140a and 1140b control a substrate bias voltage of the PMOS transistor 1110a of the first charge transfer unit 1110 and the PMOS transistor 1120b of the first switch 1120.

The PMOS transistors 1240a and 1240b of the second bias control unit 1240 are similarly connected to the PMOS transistors 1210a and 1220b so that the PMOS transistors 1240a and 1240b control a substrate bias voltage of the PMOS transistor 1210a of the second charge transfer unit 1210 and the PMOS transistor 1220b of the second switch 1120. The gate of the PMOS transistor 1240a is also connected to the gate of the PMOS transistor 1120b and to the drain of the PMOS transistor 1210a, to the drain of the PMOS transistor 1220b, and to the output terminal of the second charge storage unit 1230.

In general, a threshold voltage of a field effect transistor may be expressed by the following Equation.

Equation

Vₜ=Vₜ₀+γ[\sqrt{2φ_{f}+V_{SB}}−\sqrt{2φ_{f}}]

In Equation above, Vₜ₀ denotes a threshold voltage when V_{SB} is 0, V_{SB} denotes a voltage between source and substrate, γ denotes a process parameter, and φ_{f} denotes a physical parameter.

In an embodiment of the invention, the substrate bias voltage V_{SB} is allowed to be substantially equal to the higher one of the source and drain voltages through the first bias control unit 1140, so that a threshold voltage of the PMOS transistor 1110a of the first charge transfer unit 1110 can be fixed to Vₜ₀.

The threshold voltage value of the PMOS transistor 1110a of the first charge transfer unit 1110 is fixed by the first bias control unit 1140, so that the threshold voltage value of the PMOS transistor 1110a of the first charge transfer unit 1110 can be constantly maintained in each cell, and thus the amount of charge passing through the first charge transfer unit 1110 can be constantly maintained in each cell.

Furthermore, in the aforementioned charge backflow prevention operation, since the PMOS transistor 1120b of the first switch 1120 receives the output terminal voltage (that is, the source voltage of the PMOS transistor 1120b of the first switch 1120) of the first charge transfer unit 1110 as the substrate bias voltage, a threshold voltage of the PMOS transistor 1120b of the first switch 1120 is also fixed to Vₜ₀.

The threshold voltage value of the PMOS transistor 1120b of the first switch 1120 is fixed, so that the threshold voltage value of the PMOS transistor 1120b of the first switch 1120 can be constantly maintained in each cell, and thus the control of the charge backflow prevention operation through the PMOS transistor 1120b of the first switch 1120 can be constantly maintained in each cell.

Since the second bias control unit 1240 is similar to the first bias control unit 1140, a separate description thereof will be omitted.

Since the circuit diagram of FIG. 3 is disclosed for the purpose of the description of the unit cell 1000 according to an embodiment of the present invention, the scope of the present invention is not limited to the circuit diagram, and it will be apparent to those skilled in the art that various changes, modifications, and alternations may be made based on the circuit diagram without departing from the spirit and scope of the invention.

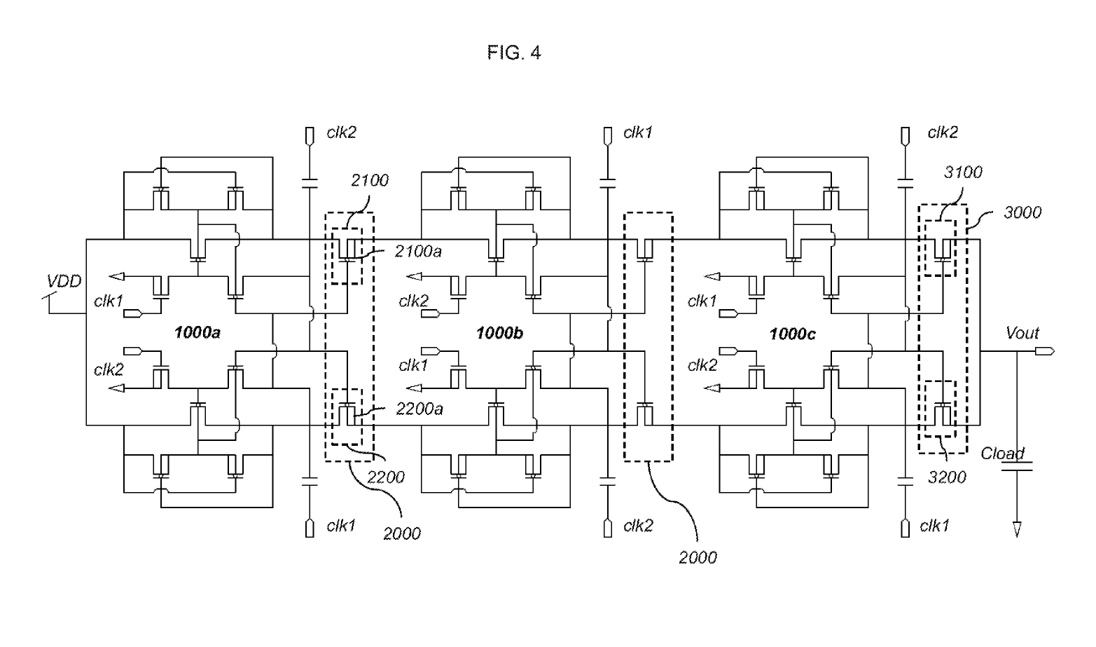

FIG. 4 is a circuit diagram illustrating the charge pumping device according to an embodiment of the present invention. The charge pumping device according to the embodiment uses three unit cells 1000 described above. These three unit cells are shown as 1000a, 1000b, and 1000c. However, in another embodiment, a different number of unit cells may be used. In the unit cell 1000a of the first stage, input terminals of a first charge transfer unit and a second charge transfer unit are commonly connected to a power supply voltage VDD. The first charge transfer unit and second charge transfer unit were similarly described in detail above with reference to FIG. 3. The charge pumping device of FIG. 4 may be called a symmetric charge pumping device.

The charge pumping device according to the embodiment shown in FIG. 4 includes a first interface unit 2000 which includes a 1-1^{th} interface section 2100 for connecting an output terminal of a first charge transfer unit of a front stage (e.g., unit cell 1000a) to an input terminal of a first charge transfer unit of a rear stage (e.g., unit cell 1000b), and a 1-2^{th} interface section 2200 for connecting an output terminal of a second charge transfer unit of the front stage to an input terminal of a second charge transfer unit of the rear stage, among the unit cells. For ease of discussion herein, the stages formed by the unit cells 1000a, 1000b, and 1000c will also be referred to as stages 1000a, 1000b, and 1000c, respectively.

In the embodiment, each of the 1-1^{th} interface section 2100 and the 1-2^{th} interface section 2200 includes a PMOS transistor. A gate of the PMOS transistor 2100a of the 1-1^{th} interface section 2100 is connected to the output terminal of the second charge transfer unit, and a gate of the PMOS transistor 2200a of the 1-2^{th} interface section 2200 is connected to the output terminal of the first charge transfer unit.

Accordingly, when a first charge storage unit of a front stage (e.g., stage 1000a) performs a charge transfer operation, a connection through the 1-1^{th} interface section 2100 is interrupted, so that the first charge storage unit of the front stage stores charges from a previous stage through the first charge transfer unit thereof.

When the first charge storage unit of the front stage 1000a performs a charge backflow prevention operation, the connection through the 1-1^{th} interface section 2100 is achieved, so that charge of the first charge storage unit of the front stage 1000a moves to a second charge storage unit of a rear stage (e.g., stage 1000b in this example) through a first charge transfer unit of the rear stage.

Since an operation of the 1-2^{th} interface section 2200 is substantially equal to the operation of the 1-1^{th} interface section 2100, a repetitive description thereof will be omitted.

The charge pumping device according to the embodiment includes a second interface unit 3000 which includes a 2-1^{th} interface section 3100 for connecting an output terminal of a first charge transfer unit of a final stage 1000c to a load capacitor Cload, and a 2-2^{th} interface section 3200 for connecting an output terminal of a second charge transfer unit of the final stage 1000c to the load capacitor Cload, between the unit cell of the final stage and the load capacitor.

In the embodiment, each of the 2-1^{th} interface section 3100 and the 2-2^{th} interface section 3200 includes a PMOS transistor. An operation of the second interface unit 3000 is basically equal to that of the first interface unit 2000. That is, the 2-1^{th} interface section 3100 transfers charge in a first charge storage unit of the final stage 1000c to the load capacitor Cload for storage while the first charge transfer unit of the final stage 1000c is performing a charge backflow prevention operation, and transfers charge in a second charge storage unit of the final stage to the load capacitor for storage while the second charge transfer unit of the final stage is performing the charge backflow prevention operation.

As described above, the charge pumping device according to an embodiment of the invention alternately pumps charge to the load capacitor for one cycle of the first clock clk1 or the second clock clk2, thereby enabling a high speed pumping operation. In an embodiment of the invention, phases of clocks applied to first switches of adjacent unit cells are opposite to each other. Thus, phases of clocks applied to the other ends of first charge storage units of the adjacent unit cells are also opposite to each other, and clocks inputted to another corresponding configuration are also the same.

In the case of the charge pumping device according to an embodiment of the invention, since voltage drop due to a threshold voltage does not occur between the input and output terminals of the first charge transfer unit and between the input and output terminals of the second charge transfer unit in the charge transfer process through the unit cell as described above, an efficient charge pumping operation is possible.

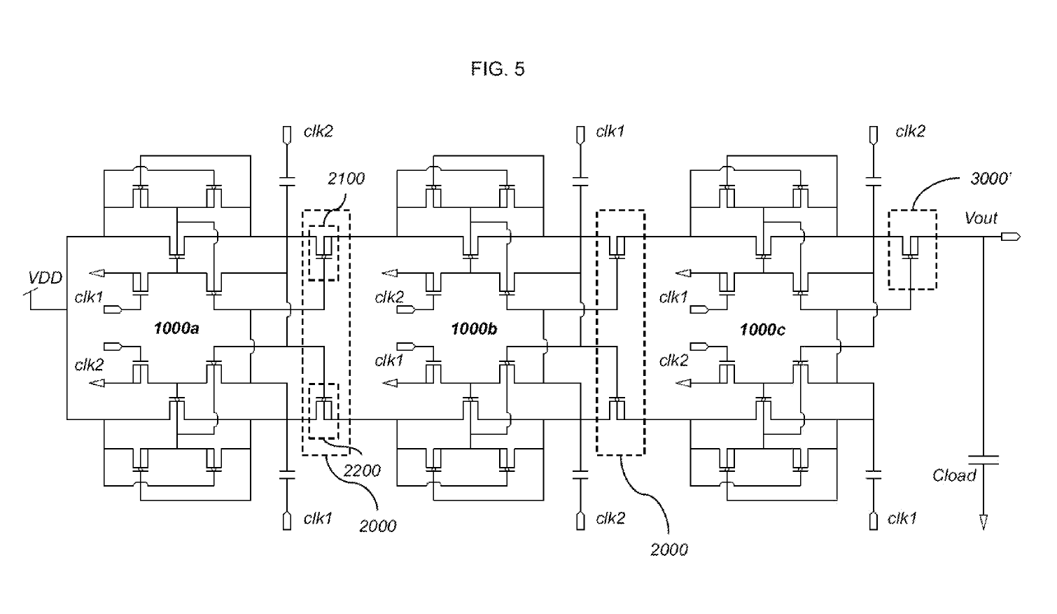

FIG. 5 is a circuit diagram of the charge pumping device according to another embodiment of the present invention. The embodiment of FIG. 5 is substantially equal to the embodiment of FIG. 4, except for the configuration of the second interface unit 3000. The charge pumping device of FIG. 5 may be called an asymmetric charge pumping device.

In the embodiment of FIG. 5, a second interface unit 3000′ includes an interface section for connecting an output terminal of a first charge transfer unit of a final stage 1000c to a load capacitor Cload, but does not have a configuration for connecting an output terminal of a second charge transfer unit of the final stage 100c to the load capacitor.

In the embodiment, a second cell of each stage performs only a function of controlling a first switch in a first cell of each stage, than a charge pumping function. Thus, for one cycle of the first clock clk1 or the second clock clk2, one-time pumping is performed only in the first cell.

In the embodiment illustrated in FIG. 5, since a second cell of each stage does not perform a charge pumping function differently from the embodiment illustrated in FIG. 4, it is possible to further reduce the size of an element as compared with the first cell of each stage. That is, the size of a transistor used in the second charge transfer unit may be smaller than that of a transistor used in the first charge transfer unit, and the capacity of a capacitor of a second charge storage unit may be smaller than that of a capacitor of a first charge storage unit.

Therefore, in the embodiment of FIG. 5, it is possible to reduce the size of an element as compared with the embodiment illustrated in FIG. 4, resulting in the reduction of the entire area of the circuit.

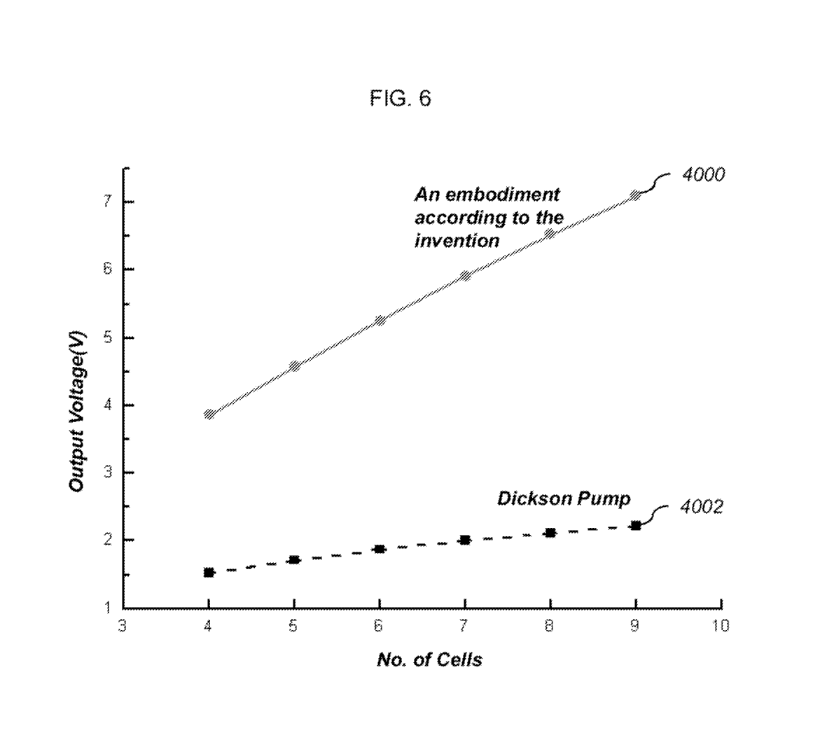

FIG. 6 is a graph illustrating pumping performance according to the number of unit cells between the charge pumping device according to an embodiment of the present invention and the conventional Dickson charge pumping device. The graph of FIG. 6 indicates an experimental result obtained in conditions that a power supply voltage is fixed to approximately 0.8 V.

In the graph, a horizontal axis denotes the number of unit cells, that is, the number of stages, and a vertical axis denotes an output voltage. In the graph, the slope of the graph indicates the degree of an increase in the output voltage according to the number of unit cells.

In the case of the charge pumping device according to an embodiment of the present invention, the slope is very large as compared with the conventional Dickson charge pumping device. In the case of the Dickson charge pumping device, it can be understood that there is a limitation in a pumping voltage obtainable when the number of unit cells is increased. Moreover, when the power supply voltage is low, it is not possible to obtain a sufficiently high voltage using the Dickson charge pumping device. As a result, the output voltage (V) value and degree of an increase in the output voltage according to the number of cells in an embodiment of the invention (as represented by the line 4000) is greater than the same output voltage parameters according to the number of cells in a Dickson charge pumping device (as represented by the line 4002).

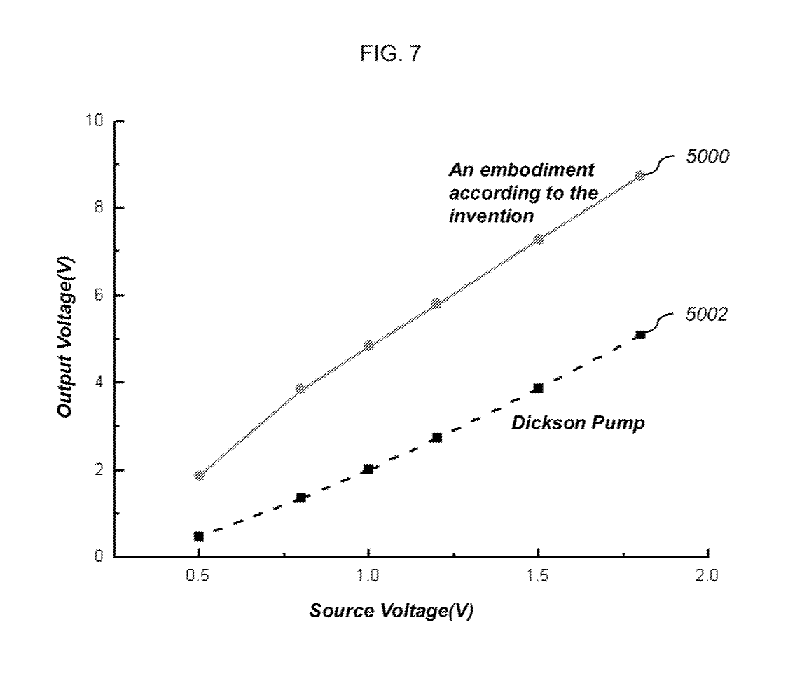

FIG. 7 is a graph illustrating a result obtained by simulating pumping performance of the asymmetric charge pumping device according to an embodiment of the present invention and the conventional Dickson charge pumping device. Each device includes four unit cells. In the graph, a horizontal axis denotes a power supply voltage and a vertical axis denotes an output voltage.

As illustrated in FIG. 7, it can be understood that the charge pumping device according to an embodiment of the present invention exhibits superior pumping performance at a low power supply voltage of approximately 1 V or less. However, it can be understood that in the conventional Dickson charge pumping device, pumping is rarely performed at approximately 1 V or less. That is, it can be understood that a difference of the pumping performance is very large at a low power supply voltage of approximately 1 V or more. The output voltage (V) value and degree of an increase in the output voltage versus the source voltage (V) in a charge pumping device in an embodiment of the invention (as represented by the line 5000) is greater than the same output voltage parameters versus the source voltage in a Dickson charge pumping device (as represented by the line 5002).

While certain embodiments have been described above, it will be understood to those skilled in the art that the embodiments described are by way of example only. Accordingly, the charge pumping device and the unit cell thereof described herein should not be limited based on the described embodiments. Rather, the charge pumping device and the unit cell thereof described herein should only be limited in light of the claims that follow when taken in conjunction with the above description and accompanying drawings.

What is claimed is:

1. A charge pumping device comprising:
a plurality of unit cells having a numeric count N of unit cells, each unit cell including:
a first cell including a first charge transfer circuit, a first switch configured to control a charge transfer operation of the first charge transfer circuit, and a first charge storage circuit having a first end connected to an output terminal of the first charge transfer circuit and storing charge, and
a second cell including a second charge transfer circuit, a second switch configured to control a charge transfer operation of the second charge transfer circuit, and a second charge storage circuit having a first end connected to an output terminal of the second charge transfer circuit and storing charge,
wherein the first switch is controlled by a first clock and the output terminal of the second charge storage circuit, the second switch is controlled by a second clock and the output terminal of the first charge storage circuit, the second clock is inputted to a second end of the first charge storage circuit, and the first clock is inputted to a second end of the second charge storage circuit;
one or more first interface circuits respectively configured to connect an output terminal of a first charge transfer circuit of a k^{th} unit cell of the plurality of unit cells, where k is a natural number from 1 to N−1, to an input terminal of a second charge transfer circuit of a (k+1)^{th} unit cell of the plurality of unit cells, and to connect an output terminal of a second charge transfer circuit of the k^{th} unit cell to an input terminal of a first charge transfer circuit of the (k+1)^{th} unit cell; and
a second interface circuit configured to connect one of output terminals of first and second charge transfer circuits of an N^{th} unit cell to one end of a load capacitor,
wherein input terminals of a first charge transfer circuit and a second charge transfer circuit of a first unit cell are commonly connected to a power supply voltage.

2. The charge pumping device according to claim 1, wherein a first charge transfer circuit of at least one unit cell includes a PMOS transistor.

3. The charge pumping device according to claim 2, wherein the at least one unit cell includes a first bias control circuit that controls a substrate bias voltage of the first charge transfer circuit of the at least one unit cell.

4. The charge pumping device according to claim 2, wherein a second charge transfer circuit of the at least one unit cell includes a PMOS transistor.

5. The charge pumping device according to claim 4, wherein the at least one unit cell includes a second bias control circuit that controls a substrate bias voltage of the second charge transfer circuit of the at least one unit cell.

6. The charge pumping device according to claim 1, wherein a first switch of at least one unit cell comprises:
a 1-1^{th} switch that is controlled by the first clock and controls charge to be transferred through a first charge storage circuit of the at least one unit cell; and
a 1-2^{th} switch that is controlled by the output terminal of a second charge transfer circuit of the at least one unit cell and substantially prevents charge from flowing back from the first charge storage circuit.

7. The charge pumping device according to claim 6, wherein the 1-1^{th} switch includes a NMOS transistor having a source grounded, a drain connected to a gate of the first charge transfer circuit, and a gate to which the first clock is inputted, and the 1-2^{th} switch includes a PMOS transistor having a drain connected to the gate of the first charge transfer circuit, a source connected to the output terminal of the first charge transfer circuit, and a gate connected to the output terminal of the second charge transfer circuit.

8. The charge pumping device according to claim 7, wherein the at least one unit cell includes a first bias control circuit that controls a substrate bias voltage of the first charge transfer circuit and a substrate bias voltage of the 1-2^{th} switch.

9. The charge pumping device according to claim 6, wherein a second switch of the at least one unit cell comprises:
a 2-1^{th} switch that is controlled by the second clock and controls charge to be transferred through the second charge storage circuit; and
a 2-2^{th} switch that is controlled by the output terminal of the first charge transfer circuit and substantially prevents charge from flowing back from the second charge storage circuit.

10. The charge pumping device according to claim 9, wherein the 2-1^{th} switch includes a NMOS transistor having a source grounded, a drain connected to a gate of the second charge transfer circuit, and a gate to which the second clock is inputted, and the 2-2^{th} switch includes a PMOS transistor having a drain connected to the gate of the second charge transfer circuit, a source connected to the output terminal of the second charge transfer circuit, and a gate connected to the output terminal of the first charge transfer circuit.

11. The charge pumping device according to claim 10, wherein the at least one unit cell includes a second bias control circuit that controls a substrate bias voltage of the second charge transfer circuit and a substrate bias voltage of the 2-2^{th} switch.

12. The charge pumping device according to claim 1, wherein a first charge transfer circuit of at least one unit cell includes a 1-1^{th} PMOS transistor, and a first switch of the at least one unit cell comprises:
a NMOS transistor having a source grounded, a drain connected to a gate of the 1-1^{th} PMOS transistor, and a gate to which the first clock is inputted; and
a 1-2^{th} PMOS transistor having a drain connected to the gate of the 1-1^{th} PMOS transistor, a source connected to the output terminal of the first charge transfer circuit, and a gate connected to the output terminal of a second charge transfer circuit of the at least one unit cell.

13. The charge pumping device according to claim 12, wherein the at least one unit cell includes a first bias control circuit that controls a substrate bias voltage of the 1-1^{th} PMOS transistor and a substrate bias voltage of the 1-2^{th} PMOS transistor.

14. The charge pumping device according to claim 12, wherein the second charge transfer circuit includes a 2-1^{th} PMOS transistor, and a second switch of the at least one unit cell comprises:
an NMOS transistor having a source grounded, a drain connected to a gate of the 2-1^{th} PMOS transistor, and a gate to which the second clock is inputted; and
a 2-2^{th} PMOS transistor having a drain connected to the gate of the 2-1^{th} PMOS transistor, a source connected to the output terminal of the second charge transfer circuit, and a gate connected to the output terminal of the first charge transfer circuit.

15. The charge pumping device according to claim 14, wherein the at least one unit cell includes a second bias control circuit that controls a substrate bias voltage of the 2-1^{th} PMOS transistor and a substrate bias voltage of the 2-2^{th} PMOS transistor.

16. The charge pumping device according to claim 1, wherein phases of the first clock and the second clock are opposite to each other.

17. The charge pumping device according to claim 1, wherein at least one first interface circuit includes:
a first interface switch connected between the output terminal of the first charge transfer circuit of a previous unit cell and the input terminal of the second charge transfer circuit of a next unit cell; and
a second interface switch connected between the output terminal of the second charge transfer circuit of the previous unit cell and the input terminal of the first charge transfer circuit of the next unit cell,
wherein the first interface switch is controlled by the output terminal of the second charge transfer circuit of the previous unit cell, and
wherein the second interface switch is controlled by the output terminal of the first charge transfer circuit of the previous unit cell.

18. A charge pumping device comprising:
a plurality of unit cells, each unit cell including:
a first cell including a first charge transfer circuit, a first switch configured to control a charge transfer operation of the first charge transfer circuit, and a first charge storage circuit having a first end connected to an output terminal of the first charge transfer circuit and storing charge, and
a second cell including a second charge transfer circuit, a second switch configured to control a charge transfer operation of the second charge transfer circuit, and a second charge storage circuit having a first end connected to an output terminal of the second charge transfer circuit and storing charge,
wherein the first switch is controlled by a first clock and the output terminal of the second charge storage circuit, the second switch is controlled by a second clock and the output terminal of the first charge storage circuit, the second clock is inputted to a second end of the first charge storage circuit, and the first clock is inputted to a second end of the second charge storage circuit;
a first interface circuit configured to connect an output terminal of a first charge transfer circuit of a first unit cell of the plurality of unit cells to an input terminal of a second charge transfer circuit of a second unit cell of the plurality of unit cells, and to connect an output terminal of a second charge transfer circuit of the first unit cell to an input terminal of a first charge transfer circuit of the second unit cell; and
a second interface circuit configured to connect one of output terminals of first and second charge transfer circuits of a final unit cell of the plurality of unit cells to one end of a load capacitor,
wherein input terminals of first and second charge transfer circuits of an initial unit cell of the plurality of unit cells are commonly connected to a power supply voltage.

19. The charge pumping device according to claim 18,
wherein at least one first cell includes a first bias circuit configured to control a bias voltage of a first charge transfer circuit, and
wherein at least one second cell includes a second bias circuit configured to control a bias voltage of a second charge transfer circuit.

20. The charge pumping device according to claim 18, wherein the first interface circuit includes:
a first interface switch connected between the output terminal of the first charge transfer circuit of the first unit cell and the input terminal of the second charge transfer circuit of the second unit cell; and
a second interface switch connected between the output terminal of the second charge transfer circuit of the first unit cell and the input terminal of the first charge transfer circuit of the second unit cell,
wherein the first interface switch is controlled by the output terminal of the second charge transfer circuit of the first unit cell, and
wherein the second interface switch is controlled by the output terminal of the first charge transfer circuit of the first unit cell.
